(19) United States
(12) Patent Application Publication
(10) Pub. No.: US 2026/0314138 A1
(43) Pub. Date: Oct. 8, 2026

(54) TRANSFER DEVICE, AND MANUFACTURING METHOD, DETECTION METHOD AND DETECTION DEVICE THEREOF

(71) Applicant: CHONGQING KONKA PHOTOELECTRIC TECHNOLOGY RESEARCH INSTITUTE CO., LTD., Chongqing (CN)

(72) Inventors: Feng ZHAI, Chongqing (CN); Chun-Lung HSIAO, Chongqing (CN); Ming-Ta TSAI, Chongqing (CN)

(73) Assignee: CHONGQING KONKA PHOTOELECTRIC TECHNOLOGY RESEARCH INSTITUTE CO., LTD., Chongqing (CN)

(21) Appl. No.: 19/484,439

(22) PCT Filed: Jun. 8, 2021
(86) PCT No.: PCT/CN2021/098972

§ 371 Date: Nov. 14, 2025

(51) Int. Cl. H10H 29/02; B29C 39/12; B29K 83/00; G01N 21/95

(52) U.S. Cl. CPC H10H 29/02; B29C 39/123; G01N 21/95; B29K 2083/00

(57) ABSTRACT

A transfer device, and a manufacturing method, a detection method and a detection device of the transfer device are provided. The transfer device includes a transfer head. A colloidal crystal layer is formed on at least one bulge of the transfer head. Based on the characteristics that a Bragg reflection effect of a colloidal crystal microsphere structure can present different light colors, whether the bulge is abnormal or not is determined according to light reflected by the colloidal crystal layer on each bulge.

### CROSS REFERENCE TO RELATED APPLICATION

This application is a National Stage Filing under 35 U.S.C. § 371 of the PCT International Application No. PCT/CN2021/098972 filed on Jun. 8, 2021, the entirety of which is herein incorporated by reference.

### TECHNICAL FIELD

The present disclosure relates to the field of chip transfer, in particular to a transfer device and a manufacturing method, a detection method and a detection device of the transfer device.

### BACKGROUND

A Micro LED, known as a next-generation display device, is sought after by various manufacturers due to its high brightness, wide color gamut coverage and high contrast ratio, and its popularity continues to rise in recent years. However, there are still many problems to be overcome in the actual manufacturing process. For example, a display panel of a Micro LED includes a plurality of pixel regions. In some application scenarios, each pixel region includes a red LED chip, a blue LED chip, and a green LED chip. In the manufacturing process of the display panel of the Micro LED, the red, green and blue chips need to be transferred from their respective growth substrates to a display backboard using a transfer head, and are electrically connected with a corresponding bonding pad on the display backboard through a bonding process. The currently used bonding process generally requires heating (mostly above 150° C.) to realize the connection between the LED chips and the display backboard using pure metal solder.

A Polydimethylsiloxane (PDMS) transfer head is an important medium to realize Micro-LED transfer, and is classified into a flat-plate transfer head and a raised transfer head. The transfer head at the current stage is formed by a high-precision template method. A bulge of the prepared raised transfer head is completely supported by PDMS glue. The material of the PDMS is thermoplastic, and may withstand a certain temperature and pressure during actual use, so that the bulge is often deformed by heat and extrusion. Since the most critical factor of the raised transfer head is the flatness between the bulges, TTV (highest point height-lowest point height) is required to be <2 um, that is, the height difference between the bulges is required to be <2 μm. The bulge of the raised transfer head is prone to irreversible deformation or damaged loss during the process of cyclic reciprocating heating and pressure. In the application, the bulge with the irreversible deformation or damaged loss is referred to as an abnormal bulge. The generation of the abnormal bulge may cause TTV changes, thereby making the raised transfer head unable to be used in the process. However, there is currently no effective means to detect whether the abnormal bulge appears on the raised transfer head.

Therefore, how to detect whether the abnormal bulge appears on the raised transfer head is an urgent problem to be solved.

### SUMMARY

In view of the above defects of the related art, embodiments of the present disclosure provide a transfer device, and a manufacturing method, a detection method and a detection device of the transfer device, which can solve the problem of how to detect whether an abnormal bulge appears on a raised transfer head in the related art.

The embodiments of the present disclosure provide a transfer device, which includes a transfer head and a colloidal crystal layer arranged on the transfer head. Herein, the transfer head includes a substrate and at least one bulge.

The at least one bulge is arranged on a back surface of the substrate and is configured to be bonded with at least one to-be-transferred chip so as to pick up and transfer the to-be-transferred chip.

The colloidal crystal layer is formed on the bulge, and at least partially covers a surface, to be attached to the to-be-transferred chip, of the bulge, wherein the colloidal crystal layer includes colloidal crystal microspheres arranged orderly.

The above transfer device includes the raised transfer head with the at least one bulge formed on the substrate, and the colloidal crystal layer is formed on the bulge of the raised transfer head. The colloidal crystal layer includes the colloidal crystal microspheres arranged orderly, and at least partially covers a surface, to be attached to the to-be-transferred chip, of the bulge. Based on the characteristics that a Bragg reflection effect of a colloidal crystal microsphere structure can present different light colors, whether the bulge is abnormal or not can be determined according to light reflected based on the Bragg reflection effect of the colloidal crystal layer on each bulge, thereby realizing the detection of the abnormal bulge on the raised transfer head, and avoiding the situation that the transfer head with the abnormal bulge is continued to be used and chip transfer fails or transfer is unqualified.

Based on the same inventive concept, the embodiments of the present disclosure also provide a manufacturing method of a transfer device. The manufacturing method is used for manufacturing the above transfer device and includes the following operations.

A transfer head mold is manufactured, wherein the transfer head mold includes a template substrate main body and a transfer head pattern formed on the template substrate main body, and the transfer head pattern includes at least one groove configured to form the bulge.

The colloidal crystal layer is formed at least at a bottom of the groove.

A preset material is filled into the transfer head pattern and curing treatment is performed to obtain the transfer head.

The transfer head mold is removed, and the colloidal crystal layer remains on the transfer head.

In the transfer device manufactured by the above manufacturing method of the transfer device, the colloidal crystal layer is formed on the surface, to be attached to the to-be-transferred chip, of the bulge. The colloidal crystal layer includes the colloidal crystal microspheres arranged orderly. Based on the characteristics that a Bragg reflection effect of a colloidal crystal microsphere structure can present different light colors, whether the bulge is abnormal or not can be determined according to light reflected based on the Bragg reflection effect of the colloidal crystal layer on each bulge, thereby realizing the detection of the abnormal bulge on the transfer head.

Based on the same inventive concept, the embodiments of the present disclosure also provide a manufacturing method of a transfer device. The manufacturing method is used for manufacturing the above transfer device and includes the following operations.

The transfer head is manufactured.

The colloidal crystal layer is formed on the bulge.

In the transfer device manufactured by the above manufacturing method of the transfer device, the colloidal crystal layer is also formed on the surface, to be attached to the to-be-transferred chip, of the bulge, so that whether the bulge is abnormal or not may also be determined according to the light reflected based on the Bragg reflection effect of the colloidal crystal layer on the bulge, thereby realizing the detection of the abnormal bulge on the transfer head.

Based on the same inventive concept, the embodiments of the present disclosure also provide a detection method of the above transfer device, and the detection method includes the following operations.

The transfer device is placed in a preset light environment, with the colloidal crystal layer on the bulge facing towards a light incident direction.

Light reflected by the colloidal crystal layer on the bulge is detected, and whether the bulge is abnormal or not is determined according to a detection result.

In the above detection method, the transfer device is placed in the preset light environment, with the surface, to be attached to the to-be-transferred chip, of the bulge of the transfer head facing towards the light incident direction, so that whether the bulge is abnormal or not can be determined according to the detection result of the light reflected by the colloidal crystal layer on the bulge, thereby realizing the detection of the abnormal bulge on the transfer head.

Based on the same inventive concept, the embodiments of the present disclosure also provide a detection device of a transfer device, and the detection device includes a light detection device.

The light detection device is configured to, in a case where the transfer device is placed in a preset light environment, with the colloidal crystal layer on the bulge facing towards a light incident direction, detect light reflected by the colloidal crystal layer on the bulge, and determine whether the bulge is abnormal or not according to a detection result.

In the light detection device, the transfer device is placed in the preset light environment, with the surface, to be attached to the to-be-transferred chip, of the bulge of the transfer head facing towards the light incident direction, so that when the colloidal crystal layer formed on the bulge faces towards the light incident direction, whether the bulge is abnormal or not can be determined according to the detection result of the light reflected by the colloidal crystal layer on the bulge, thereby realizing the detection of the abnormal bulge on the transfer head.

### BRIEF DESCRIPTION OF THE DRAWINGS

FIG. 1A is a schematic diagram of a transfer head in the related art.

FIG. 1B is a schematic diagram of the state of a transfer head in FIG. 1A after use.

FIG. 2 is a schematic structural diagram I of a transfer head device provided in an embodiment of the present disclosure.

FIG. 3 is a schematic diagram of ordered arrangement of colloidal crystal microspheres provided in an embodiment of the present disclosure.

FIG. 4 is a schematic structural diagram II of a transfer head device provided in an embodiment of the present disclosure.

FIG. 5 is a schematic structural diagram III of a transfer head device provided in an embodiment of the present disclosure.

FIG. 6 is a schematic structural diagram IV of a transfer head device provided in an embodiment of the present disclosure.

FIG. 7 is a schematic diagram of a manufacturing method of a transfer head device provided in another exemplary embodiment of the present disclosure.

FIG. 8 is a schematic flowchart of forming an alternate crystal layer provided in another exemplary embodiment of the present disclosure.

FIG. 9 is a schematic diagram of a manufacturing process of a transfer head device provided in another exemplary embodiment of the present disclosure.

FIG. 10A is a schematic diagram of a manufacturing method of a transfer head device provided in yet another exemplary embodiment of the present disclosure.

FIG. 10B is a schematic diagram of a manufacturing process of a transfer head device provided in another exemplary embodiment of the present disclosure.

FIG. 11 is a schematic flowchart of forming an alternate crystal layer provided in yet another exemplary embodiment of the present disclosure.

FIG. 12 is a schematic diagram of a detection method of a transfer head device provided in another exemplary embodiment of the present disclosure.

FIG. 13 is a schematic diagram of a hybrid band structure provided in another exemplary embodiment of the present disclosure.

FIG. 14A is a schematic structural diagram of a transfer device without an abnormal bulge provided in another exemplary embodiment of the present disclosure.

FIG. 14B is a schematic diagram of a light reflection area of a transfer device structure without an abnormal bulge provided in another exemplary embodiment of the present disclosure.

FIG. 14C is a schematic structural diagram of a transfer device with an abnormal bulge provided in another exemplary embodiment of the present disclosure.

FIG. 14D is a schematic diagram of a light reflection area of a transfer device structure with an abnormal bulge provided in another exemplary embodiment of the present disclosure.

FIG. 15 is a schematic structural diagram of a detection device of another transfer device of the present disclosure.

Reference signs are as follows:
1, 13—bulge, 11—supporting substrate, 12—bearing substrate, 121—substrate material, 131—bulge material, 14—colloidal crystal layer, 141—microsphere mixed solution, 15—template substrate main body, 151—groove, 61—light detection device, 611—wavelength collection device, 612—analysis device.

### DETAILED DESCRIPTION OF THE EMBODIMENTS

In order to facilitate the understanding of the application, the application will be described more fully below with reference to the relevant drawings. The exemplary implementations of the application are shown in the drawings. However, the application may be implemented in various different forms and is not limited to the implementations described herein. On the contrary, the purpose of providing these implementations is to make the understanding of the application more thorough and comprehensive.

Unless otherwise defined, all technical and scientific terms used herein have the same meaning as commonly understood by those skilled in the art of the application. The terms used herein is only for the purpose of describing the exemplary implementations of the application and is not intended to limit the application.

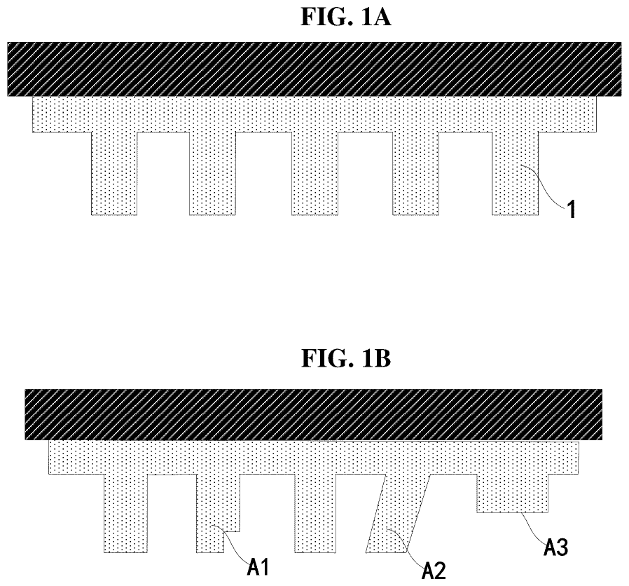

In the related art, a bulge of a raised transfer head is prone to irreversible deformation or damaged loss in the process of cyclic reciprocating heating and pressure, thereby becoming an abnormal bulge. The generation of the abnormal bulge may cause TTV changes, thereby making the raised transfer head unable to be used in the process. For example, the transfer head shown in FIG. 1A is provided with a plurality of bulges 1 configured to pick up a to-be-transferred chip. When the transfer head is configured to pick up and transfer the to-be-transferred chip, the bulge 1 is prone to irreversible deformation or damaged loss in the process of cyclic reciprocating heating and pressure, thereby becoming the abnormal bulge. For example, as shown in FIG. 1B, a part of the bulge A1 is lost, the bulge A2 is inclined, and the bulge A3 is deformed by pressure. These three bulges are all abnormal bulges. When the transfer head with the abnormal bulge is continued to be used, it is easy to cause chip transfer failure or transfer failure. However, there is currently no effective means to detect whether the abnormal bulge appears on the raised transfer head.

Based on this, the present disclosure provides a solution to solve the above technical problems, the details of which will be described in the subsequent embodiments.

The embodiment provides a transfer device, which includes a transfer head and a colloidal crystal layer. Herein, the transfer head includes a substrate.

The substrate is provided with a front surface and a back surface which are opposite to each other. The transfer head further includes at least one bulge arranged on a back surface of the substrate. The bulge is configured to be bonded with at least one to-be-transferred chip so as to pick up and transfer the to-be-transferred chip. The substrate in the embodiment may include, but not limited to, a bearing substrate, and the bulge of the transfer head is arranged on the back surface of the bearing substrate. In some examples, the substrate may further include a supporting substrate attached to the front surface of the bearing substrate, or at least partially embedded into the bearing substrate. The supporting substrate may be, but not limited to, a quartz substrate, a sapphire substrate, a glass substrate or a metal substrate.

The to-be-transferred chip in the embodiment may include, but not limited to, an LED chip, and the LED chip may be, but not limited to, a micro light-emitting chip. The micro light-emitting chip in the embodiment refers to um-level light-emitting chip, such as but not limited to at least one of a Mini LED chip and a Micro LED chip. Of course, the micro light-emitting chip may also be replaced with chips of other sizes according to requirements, which will not be repeated here. The chip in the embodiment is not limited to the light-emitting chip, and may also be equivalently replaced with other chips according to requirements.

In the embodiment, the number of bulges arranged on the back surface of the substrate may be flexibly set, and may be set as one bulge according to application requirements, or may be set as two or more bulges according to requirements. The spacing between the bulges may be flexibly set according to specific application requirements, for example, the spacing may be correspondingly set according to but not limited to the layout of a bonding pad in a corresponding chip bonding area on a circuit backboard. The circuit backboard in the embodiment may include, but not limited to, a display backboard and a lighting backboard.

In the embodiment, the colloidal crystal layer is formed on the bulge, and at least partially covers the surface, to be attached to the to-be-transferred chip, of the bulge, wherein the colloidal crystal layer includes colloidal crystal microspheres arranged orderly. Based on the characteristics that a Bragg reflection effect of a colloidal crystal microsphere structure can present different light colors, whether the bulge is abnormal or not can be determined according to light (for example, but not limited to, the color or the wavelength of the reflected light) reflected based on the Bragg reflection effect of the colloidal crystal layer on each bulge, thereby realizing the detection of the abnormal bulge on the raised transfer head, and avoiding the situation that the transfer head with the abnormal bulge is continued to be used and chip transfer fails or transfer is unqualified.

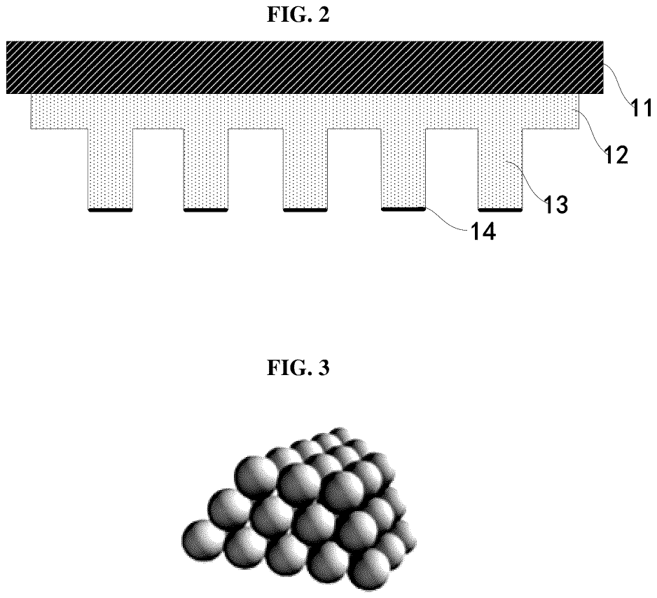

It should be understood that the colloidal crystal layer in the embodiment may completely cover the surface, to be attached to the to-be-transferred chip, of the bulge of the transfer head, or may only cover a part of the surface. For example, a transfer device in an example is shown in FIG. 2. The transfer head includes a substrate 11. The substrate includes a bearing substrate 12 and a supporting substrate 11 arranged on the bearing substrate 12, and a plurality of bulges 13 formed on the back surface of the supporting substrate 11. The transfer device further includes a colloidal crystal layer 14 completely covering the surface, to be attached to the to-be-transferred chip, of the bulge 13 of the transfer head. An example of the orderly arranged colloidal crystal microspheres included in the colloidal crystal layer 14 is shown in FIG. 3.

In an example of the embodiment, each colloidal crystal microsphere shown in FIG. 3 may be, but not limited to, a nanoscale colloidal crystal microsphere. For example, a particle size of the colloidal crystal microsphere may be greater than or equal to 173 nanometers and less than or equal to 190 nanometers. For example, in some application scenarios, a particle size of the colloidal crystal microsphere may be, but not limited to, 173 nanometers, 175 nanometers, 180 nanometers, 189 nanometers or 190 nanometers. It should be understood that, in some application examples, the particle sizes of the colloidal crystal microspheres shown in FIG. 3 may be the same, or the particle sizes of some colloidal crystal microspheres may be different. Of course, in some application scenarios in the embodiment, a particle size of the colloidal crystal microsphere may also be micron-scale or smaller than nanoscale.

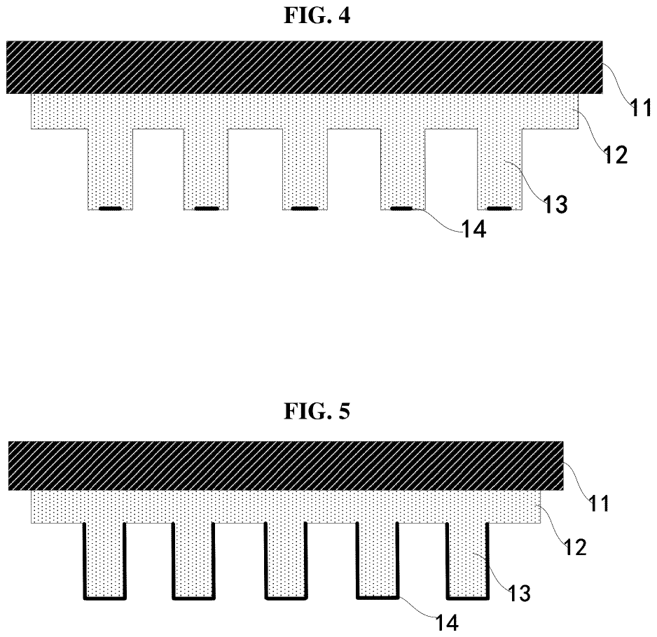

For another example, another example of the embodiment is shown in FIG. 4. The main difference between the transfer device shown in the figure and the transfer device shown in FIG. 2 is that the colloidal crystal layer 14 partially covers the surface, to be attached to the to-be-transferred chip, of the bulge 13 of the transfer head.

Yet another example of the embodiment is shown in FIG. 5. The main difference between the transfer device shown in the figure and the transfer device shown in FIG. 2 is that the colloidal crystal layer 14 completely covers the surface, to be attached to the to-be-transferred chip, of the bulge 13 of the transfer head, and covers the side surface of the bulge 13. The colloidal crystal layer 14 may completely cover the side surface of the bulge 13 or only partially cover the side surface of the bulge 13.

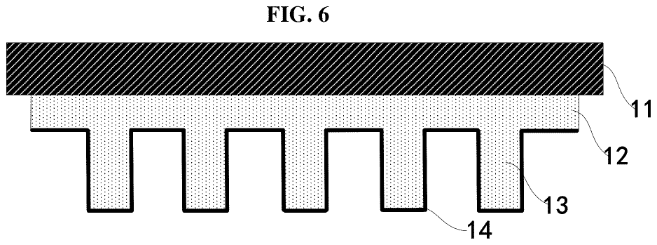

Another example of the embodiment is shown in FIG. 6. The main difference between the transfer device shown in the figure and the transfer device shown in FIG. 2 is that the colloidal crystal layer 14 completely covers the surface, to be attached to the to-be-transferred chip, of the bulge 13 of the transfer head, and covers the side surface of the bulge 13 and the back surface of the bearing substrate 12. The colloidal crystal layer 14 may completely cover the side surface of the bulge 13 or only partially cover the side surface of the bulge 13. Similarly, the colloidal crystal layer 14 may completely cover the back surface of the bearing substrate 12 or only partially cover the back surface of the bearing substrate 12.

According to the above examples, in the embodiment, the area covered by the colloidal crystal layer 14 at least partially covers the surface, to be attached to the to-be-transferred chip, of the bulge 13, and the colloidal crystal layer 14 satisfies the Bragg reflection effect. The area specifically covered with the colloidal crystal layer 14 may be set flexibly, and is not limited to the coverage areas shown in the above examples.

Similarly, in the embodiment, the material of the colloidal crystal microspheres included in the colloidal crystal layer 14 may also be flexibly selected under the condition that the Bragg reflection effect is satisfied. For example, the colloidal crystal microspheres include, but not limited to, at least one of silicon dioxide Sio2 microspheres and polymer microspheres. Herein, the polymer microspheres may include, but not limited to, at least one of polystyrene microspheres, polyacrylic acid microspheres and nanoscale microspheres formed by copolymerizing various monomers. It should be understood that, in some examples of the embodiment, the colloidal crystal microspheres included in the colloidal crystal layer 14 may be colloidal crystal microspheres of one material, such as one of the Sio2 microspheres, the polystyrene microspheres, the polyacrylic acid microspheres or the nanoscale microspheres formed by copolymerizing various monomers. Of course, the colloidal crystal microspheres included in the colloidal crystal layer 14 may alternatively include colloidal crystal microspheres of various materials, such as at least two of the Sio2 microspheres, the polystyrene microspheres, the polyacrylic acid microspheres and the nanoscale microspheres formed by copolymerizing various monomers.

In some examples of the embodiment, the colloidal crystal layer arranged on the bulge may further include: a preset material filled into gaps between the colloidal crystal microspheres of the colloidal crystal layer and used for forming the bulge. In some examples of the embodiment, the colloidal crystal microspheres may occupy 74% of the space of the colloidal crystal layer, and the remaining 26% of the space is occupied by the preset material used for forming the bulge. Of course, the space ratio occupied by the colloidal crystal microspheres and the preset material used for forming the bulge may be flexibly set according to application requirements. The preset material used for forming the bulge is filled into the gap between the colloidal crystal microspheres, so as to ensure that after the colloidal crystal layer is formed on the bulge, reliable bonding may still be formed with the to-be-transferred chip, thereby picking up and transferring the to-be-transferred chip.

In the embodiment, the above bulge may be adhered by, but not limited to, direct contact with the to-be-transferred chip, and the to-be-transferred chip may be separated from the temporary substrate or the chip on the temporary substrate may be separated from the temporary substrate or the growth substrate by the adhesive force, and may be transferred to the circuit backboard. At this time, the selection of the preset material used for forming the bulge may satisfy the adhesive force between the bulge and the to-be-transferred chip, which is greater than the bonding force between the to-be-transferred chip and the temporary substrate or the growth substrate to realize the pick-up of the chip, and is less than the bonding force between the to-be-transferred chip and the circuit backboard or other circuits after the to-be-transferred chip is transferred to the circuit backboard or other circuit boards and the bonding is completed, so as to release the to-be-transferred chip. For example, in an example, the material of the bulge may include, but not limited to, PDMS, and of course, it may be replaced with other materials satisfying the above conditions. In the example, the material of the bearing substrate may be the same as that of the bulge. At this time, the bulge and the bearing substrate may be formed by integral molding, or may not be formed by integral molding. Of course, in other examples, the material of the bulge and the material of the bearing substrate may also be different.

In other examples of the embodiment, the gap between the colloidal crystal microspheres of the colloidal crystal layer arranged on the bulge may not include the preset material used for forming the bulge, and the gap may remain empty.

The transfer device provided in the embodiment includes the raised transfer head with the at least one bulge formed on the substrate, and the colloidal crystal layer is formed on the bulge of the raised transfer head. The colloidal crystal layer includes the colloidal crystal microspheres arranged orderly. Based on the characteristics that a Bragg reflection effect of a colloidal crystal microsphere structure can present different light colors, whether the bulge is abnormal or not can be determined according to light reflected based on the Bragg reflection effect of the colloidal crystal layer on each bulge, thereby realizing the detection of the abnormal bulge on the raised transfer head, and avoiding the situation that the transfer head with the abnormal bulge is continued to be used and chip transfer fails or transfer is unqualified, which are more favorable for improving the yield of a lighting product or a display product and reducing the cost.

### Another Exemplary Embodiment

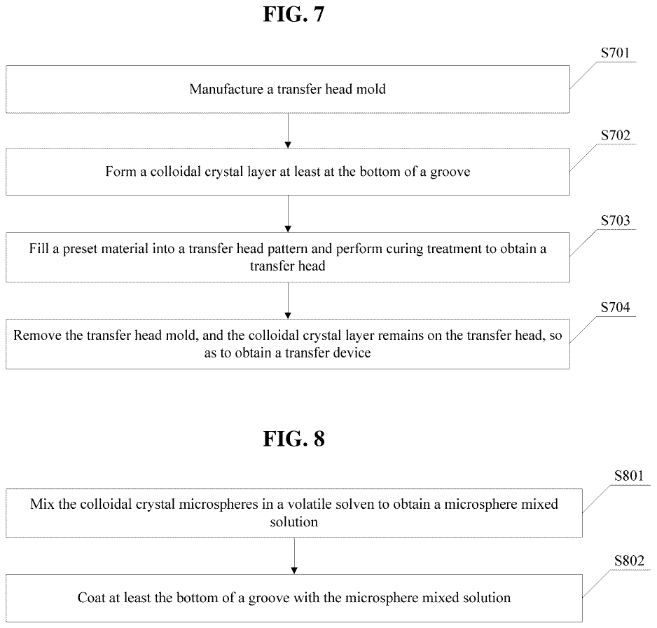

In order to facilitate the understanding, the embodiment provides a manufacturing method of a transfer device in an example for manufacturing the transfer device as shown above. In the embodiment, a colloidal crystal layer may be formed on a bulge of a transfer head in the manufacturing process of the transfer head. The manufacturing process is shown in FIG. 7, which includes, but not limited to, the following operations.

At S701, a transfer head mold is manufactured.

The transfer head mold prepared in the step includes a template substrate main body and a transfer head pattern formed on the template substrate main body. The transfer head pattern includes a corresponding groove configured to form the bulge on the transfer head. The template substrate main body in the embodiment may be, but not limited to, a silicon substrate main body, and may also be replaced with other materials. The transfer head pattern may be formed by, but not limited to, etching and the like.

At S702, the colloidal crystal layer is formed at least at a bottom of the groove.

It should be understood that, when the colloidal crystal layer is formed at the bottom of the groove, the formed colloidal crystal layer may completely cover the bottom of the groove to form the colloidal crystal layer 14 shown in FIG. 2, and may also cover a part of the bottom of the groove to form the colloidal crystal layer 14 shown in FIG. 4. Of course, the colloidal crystal layer may also cover the sidewall of the groove to form the colloidal crystal layer 14 shown in FIG. 5, and may also cover the sidewall of the groove and a surface with the transfer head pattern of the template substrate main body according to requirements, so as to form the colloidal crystal layer 14 shown in FIG. 6.

In the embodiment, the manner of forming the colloidal crystal layer at least at the bottom of the groove is shown in FIG. 8, which may include, but not limited to, the following operations.

At S801, the colloidal crystal microspheres are mixed in a volatile solvent to obtain a microsphere mixed solution.

The matched colloidal crystal microspheres are selected and dispersed in the volatile solvent to obtain the microsphere mixed solution. The selected volatile solvent has no effect on the preset material used for forming the bulge. For example, when the preset material is the PDMS material, the selected volatile solvent may be, but not limited to, an oil phase solvent. For example, isopropanol and other inert solvents (oil phase solvents without an aqueous phase) that are rapidly volatile and have no effect on the PDMS material, and the colloidal crystal microspheres (such as the SiO2 microspheres) are dispersed in the isopropanol and other inert solvents that are rapidly volatile and have no effect on the PDMS material.

At S802, at least the bottom of the groove is coated with the microsphere mixed solution.

After at least the bottom of the groove is coated with the microsphere mixed solution, through the volatilization of the volatile solvent, the colloidal crystal microspheres form a three-dimensional ordered body-centered cubic or face-centered cubic structure similar to that shown in FIG. 3 by self-assembly under gravity.

In some examples of the embodiment, the bottom of the groove is uniformly coated with the microsphere mixed solution by, but not limited to, inkjet printing technology or spraying technology.

At S703, a preset material is filled into the transfer head pattern and curing treatment is performed to obtain the transfer head.

In the embodiment, after the preset material is filled into the transfer head pattern, a part of the preset material is filled into the gap between the colloidal crystal microspheres.

For example, in some examples, the preset material configured to form the transfer head is filled into the transfer head pattern by, but not limited to, molding, spraying, spin coating, and the like. In the example, the bulge may be made of the PDMS material, which may be configured to bond the chip, and the adhesiveness is stronger than that of the bonding adhesive on the temporary substrate, but weaker than the welding force of the metal solder after soldering. The PDMS material in the embodiment may be selected from a UV curable silicone material. The UV curable silicone material has low thermal curing shrinkage, and the actually cured array structure has the best matching ability with the actual design, which may further improve the yield of the bulge.

At S704, the transfer head mold is removed, and the colloidal crystal layer remains on the transfer head, so as to obtain the transfer device.

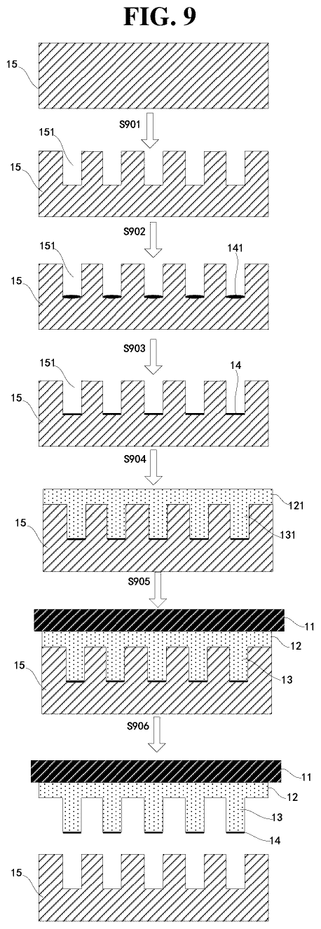

In order to facilitate further understanding, the embodiment is described below with reference to the exemplary manufacturing process of a transfer device shown in FIG. 7 as an example, as shown FIG. 9, which includes, but not limited to, the following operations.

At S901, after the template substrate main body 15 is cleaned, the transfer head pattern is formed on the template substrate main body 15. The transfer head pattern includes the groove 151 configured to form the bulge.

At S902, at least the bottom of the groove of the transfer head pattern is coated with the microsphere mixed solution 141.

At S903, after the volatile solvent is volatilized, the colloidal crystal microspheres form the colloidal crystal layer 14 by self-assembly under gravity.

At S904, the preset material is filled into the transfer head pattern and curing treatment is performed to obtain the transfer head.

In the embodiment, after the preset material is filled into the transfer head pattern, a part of the preset material is filled into the gap between the colloidal crystal microspheres. As shown in FIG. 9, the filled preset material includes a substrate material 121 configured to form the bearing substrate and a bulge material 131 used for forming the bulge.

At S905, the supporting substrate 11 is attached to the filled preset material, and curing treatment is performed on the preset material to obtain the transfer head.

At S906, the transfer head mold is removed, and the colloidal crystal layer 14 remains on the transfer head, so as to obtain the transfer device.

In the transfer device prepared by the above method, the colloidal crystal layer is formed on the bulge of the transfer device, and Based on the characteristics that a Bragg reflection effect of a colloidal crystal microsphere structure can present different light colors, whether the bulge is abnormal or not can be determined according to light reflected based on the Bragg reflection effect of the colloidal crystal layer on each bulge, thereby avoiding various problem caused by the fact that the transfer head with the abnormal bulge is continued to be used. In the embodiment, after the transfer device is obtained, the transfer device may pick up and transfer the to-be-transferred chip, and then the transfer head of the transfer device may be detected.

### Yet Another Exemplary Embodiment

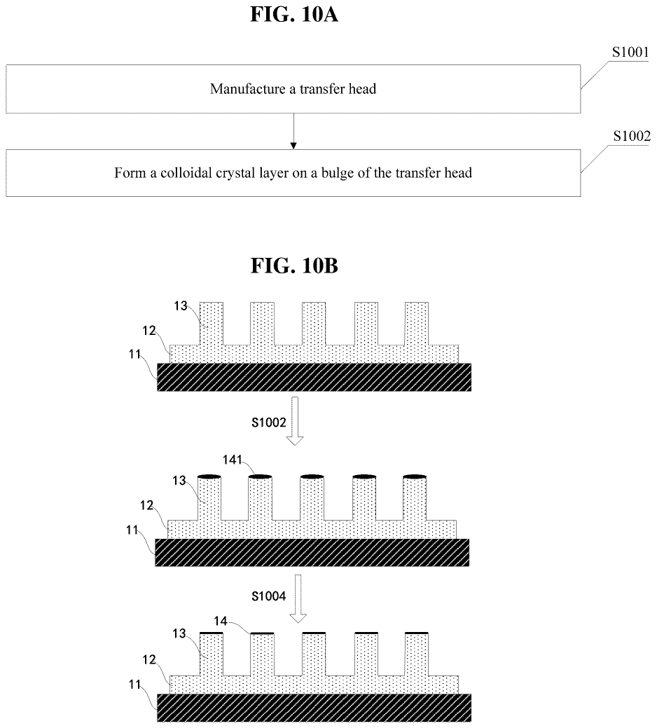

In order to facilitate the understanding, the embodiment provides a manufacturing method of a transfer device in another example, which is configured to manufacture the transfer device as shown above. In the embodiment, after a transfer head is obtained, a colloidal crystal layer may be formed on a bulge of the transfer head. The manufacturing process is shown in FIG. 10A, which includes, but not limited to, the following operations.

At S1001, the transfer head is manufactured.

In an example, the manner of manufacturing the transfer head may be, but not limited to, the manner shown in FIG. 9, with the difference that S902 and S903 are omitted.

At S1003, the colloidal crystal layer is formed on the bulge.

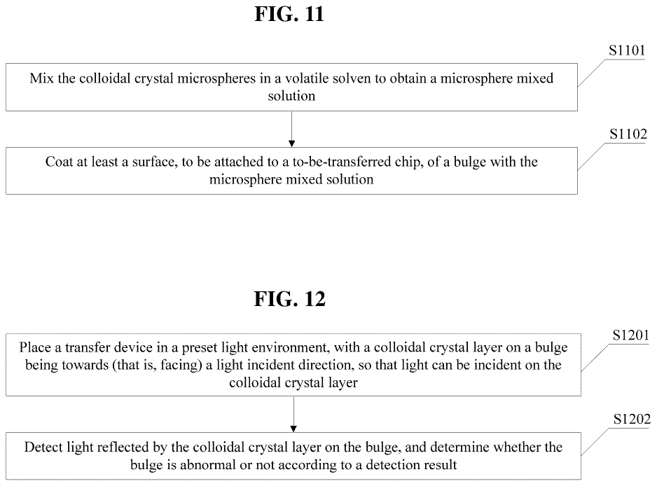

For example, in an example, the process of forming the colloidal crystal layer on the bulge is shown in FIG. 11, which may include, but not limited to, the following operations.

At S1101, the colloidal crystal microspheres are mixed in a volatile solvent to obtain a microsphere mixed solution.

The step may adopt, but not limited to, the steps shown in the above S801, which will not be repeated here.

At S1102, at least the surface, to be attached to the to-be-transferred chip, of the bulge is coated with the microsphere mixed solution. Through the volatilization of the volatile solvent, the colloidal crystal microspheres form the colloidal crystal layer by self-assembly under gravity.

The area coated with the microsphere mixed solution on the bulge may be flexibly selected according to requirements. For example, referring to the colloidal crystal layer shown in FIG. 2, FIG. 4 to FIG. 6, the corresponding area on the transfer head may be coated with the microsphere mixed solution, which will not be repeated here.

In some examples of the embodiment, after the transfer head is manufactured in the above S1001, and before the colloidal crystal layer is formed on the bulge, the method may further include the following operation.

The to-be-transferred chip is transferred using the manufactured transfer head, so that the colloidal crystal layer may be directly formed on the used transfer head, and whether the bulge is abnormal or not is determined according to the light reflected based on the Bragg reflection effect of the colloidal crystal layer, thereby realizing the detection of the abnormal bulge on the raised transfer head.

In order to facilitate further understanding, the embodiment is described below with reference to the exemplary manufacturing process of the transfer device shown in FIG. 10A as an example, as shown in FIG. 10B, which includes, but not limited to the following operations.

At S1002, the bulge 13 of the manufactured transfer head is coated with the microsphere mixed solution 141.

At S1004, after the volatile solvent is volatilized, the colloidal crystal microspheres form the colloidal crystal layer 14 on the bulge 13 by self-assembly under gravity.

### Another Exemplary Embodiment

The embodiment provides a detection method for detecting the transfer device shown in the above embodiments, as shown in FIG. 12, which includes, but not limited to, the following operations.

At S1201, the transfer device is placed in a preset light environment, and the colloidal crystal layer on the bulge is towards (that is, faces) the light incident direction, so that light can be incident on the colloidal crystal layer.

In the embodiment, the preset light environment in S1201 may be a preset natural light environment or a preset light source irradiation environment, as long as the light incident on the colloidal crystal layer on the bulge satisfies the detection condition.

At S1202, light reflected by the colloidal crystal layer on the bulge is detected, and whether the bulge is abnormal or not is determined according to a detection result.

In order to facilitate the understanding, the example describes the principle of Bragg reflection below according to a following Bragg formula (that is, the following formula (1):

$$k * λ = 2 * \sqrt{\frac{2}{3}} * \sqrt{{n}^{2} - {sin}^{2} θ} * D \qquad ( 1 )$$

In the above formula (1), k is a coefficient, D is a particle size of the colloidal crystal microsphere, n is a refractive index of the colloidal crystal microsphere, and θ is a light incident angle. Therefore, when the material of the colloidal crystal microspheres is selected, the refractive index n may be determined. For the bulge without abnormality, the normal light incident angle θ may be obtained under the preset light environment, and then a preset standard color may be selected to determine its wavelength. For example, when blue is selected, the wavelength λ of blue may be determined, and then the above parameters may be substituted into the above formula (1) to obtain a value of the particle size D of the crystal microsphere. Furthermore, when the colloidal crystal layer is formed, the colloidal crystal layer may be formed using the determined material and particle size of the colloidal crystal microsphere. In this way, when the transfer head is in the same detection environment, for the bulge without abnormality on the transfer head, the color of the light reflected by the colloidal crystal layer on the bulge is the same as the preset standard color or the difference is within the preset standard range. However, the color of the light reflected by the colloidal crystal layer on the abnormal bulge with abnormality is the same as the preset standard color, or the difference is not within the preset standard range.

Therefore, in an example of the embodiment, the operation that the light reflected by the colloidal crystal layer on the bulge is detected, and whether the bulge is abnormal or not is determined according to the detection result in S1202 may include the following operations.

An actual color of the light reflected by the colloidal crystal layer on the bulge is observed, and whether the bulge is abnormal or not is determined according to the difference between the actual color and the preset standard color. The observation in the embodiment may be directly and manually observed through vision, and the detection manner is simple and effective.

For example, in an example, taking the colloidal crystal microspheres as Sio2 microspheres as an example, n is a fixed value, and the particle size of the selected Sio2 microsphere is between 173 nanometers and 190 nanometers. At this time, the wavelength of the light reflected by the colloidal crystal layer is in the band of 420 nanometers to 460 nanometers, and the light is blue. Therefore, in some examples, the Sio2 microsphere with the particle size between 173 nanometers and 190 nanometers may be selected to form the colloidal crystal layer, and the preset standard color is set to be blue, so that whether the bulge is abnormal or not can be determined by observing whether an actual color of the light reflected by the colloidal crystal layer on the bulge is blue or not, if not, the bulge can be determined to be abnormal.

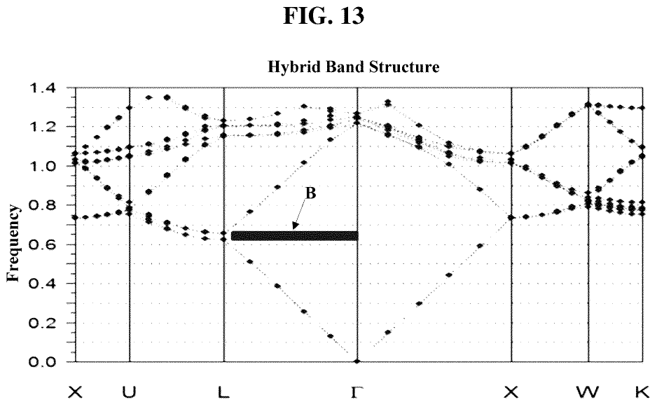

As shown in FIG. 13, in order to facilitate the understanding, the embodiment is verified below with reference to the schematic diagram of a hybrid band structure shown in FIG. 13.

In FIG. 13, the area shown in B represents an incomplete band gap of a colloidal crystal template of a face-centered cubic structure in a Γ−L area, and the corresponding wavelength range is calculated according to a formula: λ=α/ω, where λ refers to a wavelength, α refers to a normalized constant of a colloidal crystal, and o is a normalized frequency of the colloidal crystal. It may be seen from the software simulation that: taking an SiO2 colloidal crystal with 189 nm face-centered cubic structure as an example, the normalized frequency range is 0.62 to 0.66. Through calculation, the reflection wavelength range is 436 nanometers to 465 nanometers, and the wavelength of the blue light is 457 nanometers within its theoretical reflection range. Therefore, it may be verified that the above detection manner in the embodiment is feasible and accurate from both theoretical calculation and model simulation.

Based on the above principles, after detection, for a specific single blue light wavelength, the particle size of the Sio2 microsphere is selected to be 189 nm, and the blue wavelength of 457 nm is shown. Therefore, in some examples, the Sio2 microsphere with the particle size of 189 nm may be selected to form the colloidal crystal layer, and the preset standard color is blue. It should be understood that on the basis of the above principles, the preset standard color may be adjusted correspondingly by flexibly adjusting at least one of the material and a particle size of the colloidal crystal microsphere, which is not limited to the Sio2 material and the corresponding relationship between the particle size and the blue wavelength in the above example.

In yet another example of the embodiment, the operation that the light reflected by the colloidal crystal layer on the bulge is detected, and whether the bulge is abnormal or not is determined according to the detection result in S1202 may further include the following operations.

An actual wavelength λ1 of the light reflected by the colloidal crystal layer on the bulge is obtained.

An actual light incident angle θ1 of the bulge is calculated according to λ1 by a following formula (2):

$$k * λ 1 = 2 * \sqrt{\frac{2}{3}} * \sqrt{{n}^{2} - {sin}^{2} θ1} * D \qquad ( 2 )$$

In the above formula (2), k is the coefficient, D is a particle size of the colloidal crystal microsphere, and n is the refractive index of the colloidal crystal microsphere.

Whether the bulge is abnormal or not is determined according to the difference between the actual light incident angle θ1 and the preset standard light incident angle θ₀. The standard light incident angle θ₀ in the embodiment is an incident angle of light obtained under the above detection environment when the bulge is not abnormal. Therefore, according to the difference between the actual light incident angle θ1 and the preset standard light incident angle θ₀, the situation such as extrusion deformation, loss or inclination of the corresponding bulge may be determined. The deformation amount capable of representing the corresponding bulge may also be determined according to the specific difference between the two.

It may be seen that through the detection method provided in the embodiment, when the bulge on the transfer head is deformed under pressure, it may not be recovered. According to the Bragg formula, the actual light incident angle changes due to deformation, that is, θ in the formula (1) changes, and when D and n are determined, λ changes, so that the color of the light reflected by the colloidal crystal layer changes, and then the color difference may be shown. In some examples, when the bulge is in different extrusion situations, the colors of the light reflected by the colloidal crystal layer on the bulge are different. Through statistics, the specific extrusion situation may be further determined according to the corresponding light color, such as the color corresponding to different deformation amounts, etc., so that the use state of the bulge may be judged intuitively according to the color of the light reflected by the colloidal crystal layer on each bulge. The test is simple, the efficiency is high, the cost is low, and the accuracy rate is high.

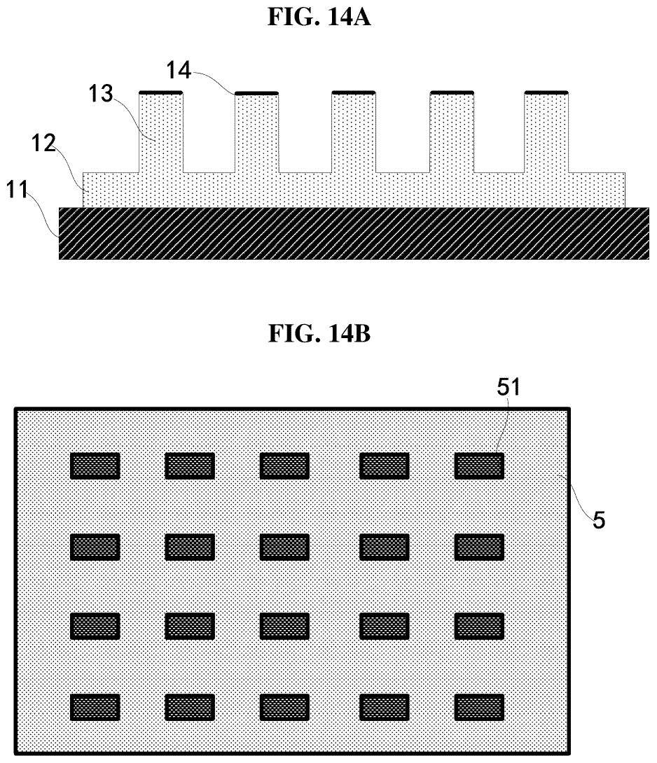

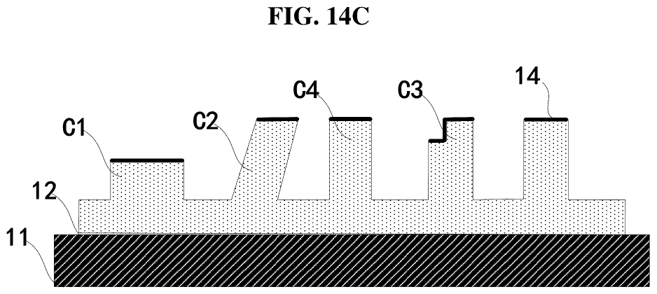

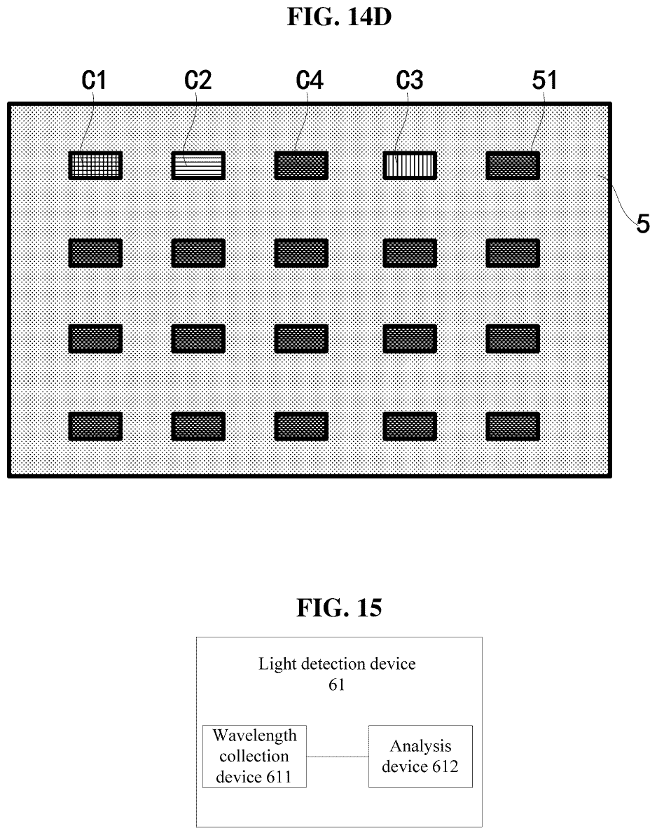

In order to facilitate the understanding, the following description is made with reference to FIG. 14A to FIG. 14D as examples.

As shown in FIG. 14A to FIG. 14B, in the state shown in FIG. 14A, each bulge 13 on the transfer head is in a normal state, and then in the preset light environment, a reflected light area 51 of the colloidal crystal layer is blue.

As shown in FIG. 14C, after the transfer device in FIG. 14A is used for a period of time, the bulges C1, C2 and C3 are abnormal, and the bulge C4 is normal. In the same detection environment, as shown in FIG. 14D, the reflected light areas corresponding to the bulge C1, C2, and C3 are no longer blue. Therefore, whether the bulge becomes the abnormal bulge during use may be intuitively determined according to the color of the reflected light area corresponding to the bulge.

The embodiment also provides a detection device of the transfer device shown in the above embodiments, as shown in FIG. 15, which includes, but not limited to, a light detection device 61.

The light detection device 61 is configured to, in a case where the transfer device is placed in a preset light environment, with the surface, to be attached to the to-be-transferred chip, of the bulge facing towards the light incident direction, detect the light reflected by the colloidal crystal layer on the bulge, and determine whether the bulge is abnormal or not according to a detection result. Herein, the detection process may refer to, but not limited to, the above examples, which will not be repeated here.

In other examples of the embodiment, the detection device may further include a conveying device configured to convey a to-be-detected transfer device in the preset light environment, or a light source device configured to generate a corresponding light source, and the like.

Referring to FIG. 15, in some examples of the embodiment, the light detection device 61 may include, but not limited to, a wavelength collection device 611 and an analysis device 612.

The wavelength collection device 611 is configured to collect an actual wavelength λ1 of the light reflected by the colloidal crystal layer on the bulge. The wavelength collection device 611 may be, but not limited to, a spectrometer.

The analysis device 612 is configured to calculate an actual light incident angle θ1 of the bulge according to λ1 by the following formula (2), and determine whether the bulge is abnormal or not according to a difference between the actual light incident angle θ1 and a preset standard light incident angle θ₀.

### Yet Another Exemplary Embodiment

The embodiment also provides a display screen, which includes a frame and a display panel. The display panel is fixed on the frame. The display panel includes a display backboard, and a plurality of micro light-emitting chips arranged on the display backboard. Herein, the plurality of micro light-emitting chips are transferred to the display backboard through the transfer device in the above embodiments, so that the micro light-emitting chips on the display backboard have better consistency after bonding, thereby improving the display effect of the display screen. The display screen may be applied to, but not limited to, various smart mobile terminals, vehicle terminals, PCs, monitors, electronic advertising boards, and the like.

The embodiment also provides a spliced display screen, which may be formed by splicing at least two display screens as shown above. Since the micro light-emitting chips of the display screen have better consistency after bonding, the consistency of the micro light-emitting chips between the spliced display screens after bonding may be further ensured, and the visual effect is improved.

It should be understood that the application of the disclosure is not limited to the above examples. For those of ordinary skill in the art, improvements or transformations may be made according to the above descriptions, and all these improvements and transformations should belong to the scope of protection of the appended claims of the disclosure.

1. A transfer device, comprising: a transfer head and a colloidal crystal layer arranged on the transfer head, wherein the transfer head comprises:
a substrate, and at least one bulge arranged on a back surface of the substrate and configured to be bonded with at least one to-be-transferred chip so as to pick up and transfer the to-be-transferred chip; and
the colloidal crystal layer is formed on the bulge, and at least partially covers a surface, to be attached to the to-be-transferred chip, of the bulge, wherein the colloidal crystal layer comprises colloidal crystal microspheres arranged orderly.

2. The transfer device according to claim 1, wherein each colloidal crystal microsphere is a nanoscale colloidal crystal microsphere, and a particle size of the colloidal crystal microsphere is greater than or equal to 173 nanometers and less than or equal to 190 nanometers.

3. The transfer device according to claim 2, wherein the particle size of the colloidal crystal microsphere is 189 nanometers.

4. The transfer device according to claim 1, wherein the colloidal crystal microsphere comprises at least one of a silicon dioxide microsphere and a polymer microsphere.

5. The transfer device according to claim 1, wherein the colloidal crystal layer completely covers the surface, to be attached to the to-be-transferred chip, of the bulge.

6. The transfer device according to claim 1, wherein the colloidal crystal layer further comprises a preset material filled into gaps between the colloidal crystal microspheres and used for forming the bulge.

7. A manufacturing method of the transfer device of claim 1, wherein the manufacturing method comprises:
manufacturing a transfer head mold, wherein the transfer head mold comprises a template substrate main body and a transfer head pattern formed on the template substrate main body, and the transfer head pattern comprises at least one groove configured to form the bulge;
forming the colloidal crystal layer at least at a bottom of the groove;
filling a preset material into the transfer head pattern and performing curing treatment to obtain the transfer head; and
removing the transfer head mold, and remaining the colloidal crystal layer on the transfer head.

8. The manufacturing method according to claim 7, wherein forming the colloidal crystal layer at least at the bottom of the groove comprises:
mixing the colloidal crystal microspheres in a volatile solvent to obtain a microsphere mixed solution; and
coating at least the bottom of the groove with the microsphere mixed solution, so that the colloidal crystal microspheres form the colloidal crystal layer by self-assembly under gravity through volatilization of the volatile solvent.

9. The manufacturing method according to claim 8, wherein the preset material comprises Polydimethylsiloxane (PDMS), and the volatile solvent is an oil phase solvent.

10. A manufacturing method the transfer device of claim 1, wherein the manufacturing method comprises:
manufacturing the transfer head; and
forming the colloidal crystal layer on the bulge.

11. The manufacturing method according to claim 10, wherein forming the colloidal crystal layer on the bulge comprises:
mixing the colloidal crystal microspheres in a volatile solvent to obtain a microsphere mixed solution; and
coating at least the surface, to be attached to the to-be-transferred chip, of the bulge with the microsphere mixed solution, so that the colloidal crystal microspheres form the colloidal crystal layer by self-assembly under gravity through volatilization of the volatile solvent.

12. The manufacturing method according to claim 10, wherein after manufacturing the transfer head and before forming the colloidal crystal layer on the bulge, the method further comprises:
transferring the to-be-transferred chip using the manufactured transfer head.

13. A detection method of the transfer device of claim 1, wherein the detection method comprises:
placing the transfer device in a preset light environment, with the colloidal crystal layer on the bulge facing towards a light incident direction; and
detecting light reflected by the colloidal crystal layer on the bulge, and determining whether the bulge is abnormal or not according to a detection result.

14. The detection method according to claim 13, wherein the preset light environment is a preset natural light environment, or a preset light source illumination environment.

15. The detection method according to claim 13, wherein detecting the light reflected by the colloidal crystal layer on the bulge, and determining whether the bulge is abnormal or not according to the detection result comprises:
observing an actual color of the light reflected by the colloidal crystal layer on the bulge, and determining whether the bulge is abnormal or not according to a difference between the actual color and a preset standard color.

16. The detection method according to claim 15, wherein a particle size of the colloidal crystal microsphere is greater than or equal to 173 nanometers and less than or equal to 190 nanometers, and the preset standard color is blue.

17. The detection method according to claim 13, wherein detecting the light reflected by the colloidal crystal layer on the bulge, and determining whether the bulge is abnormal or not according to the detection result comprises:
obtaining an actual wavelength λ1 of the light reflected by the colloidal crystal layer on the bulge;
calculating an actual light incident angle θ1 of the bulge according to λ1 by a following formula;
$$k * λ 1 = 2 * \sqrt{\frac{2}{3}} * \sqrt{{n}^{2} - {sin}^{2} θ1} * D ,$$
where k is a coefficient, D is a particle size of the colloidal crystal microsphere, and n is a refractive index of the colloidal crystal microsphere; and
determining whether the bulge is abnormal or not according to a difference between the actual light incident angle θ1 and a preset standard light incident angle θ₀.

18. A detection device of the transfer device of claim 1, wherein the detection device comprises:
a light detection device, configured to, in a case where the transfer device is placed in a preset light environment, with the colloidal crystal layer on the bulge facing towards a light incident direction, detect light reflected by the colloidal crystal layer on the bulge, and determine whether the bulge is abnormal or not according to a detection result.

19. The detection device according to claim 18, wherein the light detection device comprises:
a wavelength collection device, configured to collect an actual wavelength λ1 of the light reflected by the colloidal crystal layer on the bulge; and
an analysis device, configured to calculate an actual light incident angle θ1 of the bulge according to λ1 by a following formula, and determine whether the bulge is abnormal or not according to a difference between the actual light incident angle θ1 and a preset standard light incident angle θ₀;
$$k * λ 1 = 2 * \sqrt{\frac{2}{3}} * \sqrt{{n}^{2} - {sin}^{2} θ1} * D ,$$
where k is a coefficient, D is a particle size of the colloidal crystal microsphere, and n is a refractive index of the colloidal crystal microsphere.

20. The detection device according to claim 18, wherein the light detection device is configured to:
observe an actual color of the light reflected by the colloidal crystal layer on the bulge, and determine whether the bulge is abnormal or not according to a difference between the actual color and a preset standard color.
